(19) United States
(12) Patent Application Publication
(10) Pub. No.: US 2013/0230982 A1
(43) Pub. Date: Sep. 5, 2013

(54) METHOD FOR MANUFACTURING SEMICONDUCTOR DEVICE

(71) Applicant: Toshiyuki MORITA, Mie-ken (JP)

(72) Inventor: Toshiyuki MORITA, Mie-ken (JP)

(73) Assignee: Kabushiki Kaisha Toshiba, Tokyo (JP)

(21) Appl. No.: 13/598,688

(22) Filed: Aug. 30, 2012

(30) Foreign Application Priority Data
Nov. 10, 2011 (JP) 2011-246153

(51) Int. Cl. H01L 21/48; H01L 21/768

(52) U.S. Cl. CPC H01L 21/486; H01L 21/76841
USPC 438/653; 438/652

(57) ABSTRACT

According to one embodiment, a method for manufacturing a semiconductor device includes forming a first copper film in a first recess and a second recess having a width narrower than the first recess formed in an insulating layer above a substrate while the substrate is heated to a reflow temperature at which copper flows. The method includes forming a second copper film having an impurity concentration higher than the first copper film above the first copper film with lower flowability than the forming the first copper film.

### CROSS-REFERENCE TO RELATED APPLICATION

This application is based upon and claims the benefit of priority from Japanese Patent Application No. 2011-246153, filed on Nov. 10, 2011; the entire contents of which are incorporated herein by reference.

### FIELD

Embodiments described herein relate generally to a method for manufacturing a semiconductor device.

### BACKGROUND

A damascene method for burying copper in an interconnection groove formed in an insulating layer is known as a method for forming a copper interconnection. If the interconnection becomes increasingly finer, burying copper in a groove or a hole having a narrower width and a higher aspect ratio will be needed.

### BRIEF DESCRIPTION OF THE DRAWINGS

FIGS. 1A to 2D are schematic sectional views showing a method for manufacturing a semiconductor device of a first embodiment;

FIG. 3 is a schematic sectional view showing a method for manufacturing a semiconductor device of a second embodiment; and

FIG. 4 is a schematic view of a sputtering system.

### DETAILED DESCRIPTION

According to one embodiment, a method for manufacturing a semiconductor device includes forming a first copper film in a first recess and a second recess having a width narrower than the first recess formed in an insulating layer above a substrate while the substrate is heated to a reflow temperature at which copper flows. The method includes forming a second copper film having an impurity concentration higher than the first copper film above the first copper film with lower flowability than the forming the first copper film.

The embodiments will be described below with reference to the drawings. The same reference numerals are attached to the same element in each drawing.

The method for manufacturing a semiconductor device of the embodiments includes a process in which copper is buried in a recess such as a groove or hole formed in an insulating layer, a formation process of a copper interconnection by a so-called damascene method.

When burying copper in a recess, the electrolytic plating method excels in burying properties. The electrolytic plating method uses a substrate on which a copper film called a seed layer as a cathode and causes copper ions contained in a plating solution to deposit on the seed layer. Burying properties of copper by the electrolytic plating method greatly depends on a coatability of the seed layer formed in a recess. When a coating defect of the seed layer arises, a burying defect (void) of copper could be caused.

Thus, according to the embodiments described below, a method capable of forming a copper film functioning as a seed layer in electrolytic plating in a plurality of recesses having relatively different widths simultaneously with good coatability is provided.

### First Embodiment

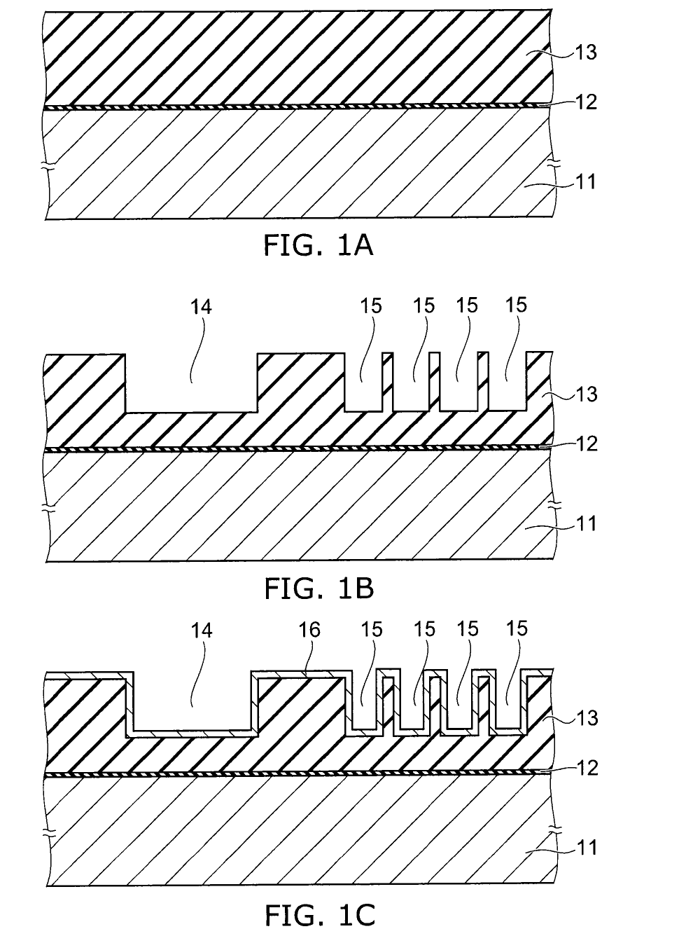

FIGS. 1A to 2D are schematic sectional views showing the method for forming a copper interconnection of the method for manufacturing a semiconductor device according to the first embodiment.

As shown in FIG. 1A, an insulating film 12 is formed on a substrate 11 and an insulating layer 13 is further formed on the insulating film 12. The substrate 11 is, for example, a silicon substrate and has a transistor (not shown) or the like formed on the substrate 11.

The insulating film 12 is, for example, a silicon oxide film formed on the silicon substrate surface by thermal oxidation and the thickness of the insulating film 12 is about 20 nm. The insulating layer 13 is made of, for example, a SiOC material whose dielectric constant is lower than that of the silicon oxide film and the thickness of the insulating layer 13 is about 300 nm. The insulating layer 13 is formed by, for example, the chemical vapor deposition (CVD) method.

A resist mask (not shown) is formed on the insulating layer 13 and, as shown in FIG. 1B, a first recess 14 and a second recess 15 are formed simultaneously in the insulating layer 13 by reactive ion etching (RIE) using the resist mask.

The first recess 14 and the second recess 15 are each a groove or a hole and the depth of each is about 250 nm. The width of the first recess 14 is, for example, 500 nm and the width of the second recess 15 is narrower than the width of the first recess 14 and is, for example, 50 nm.

The resist mask is removed by, for example, a wet process and then, as shown in FIG. 1C, a barrier metal 16 is conformally formed along the inner wall of the first recess 14, the inner wall of the second recess 15, and the top surface of the insulating layer 13. The barrier metal 16 is, for example, a tantalum film formed by a sputtering process and the thickness of the barrier metal 16 is about 15 nm.

The barrier metal 16 excels in adhesive properties to copper buried in the first recess 14 and the second recess 15 and also prevents copper from spreading to the side of the substrate 11. At least one of tantalum, titanium, titanium nitride, tantalum nitride, and tungsten nitride can be used as the barrier metal 16.

As shown in FIG. 2B, a first copper film 21 and a second copper film 22 are formed on the barrier metal 16. The first copper film 21 and the second copper film 22 are formed by the sputtering process.

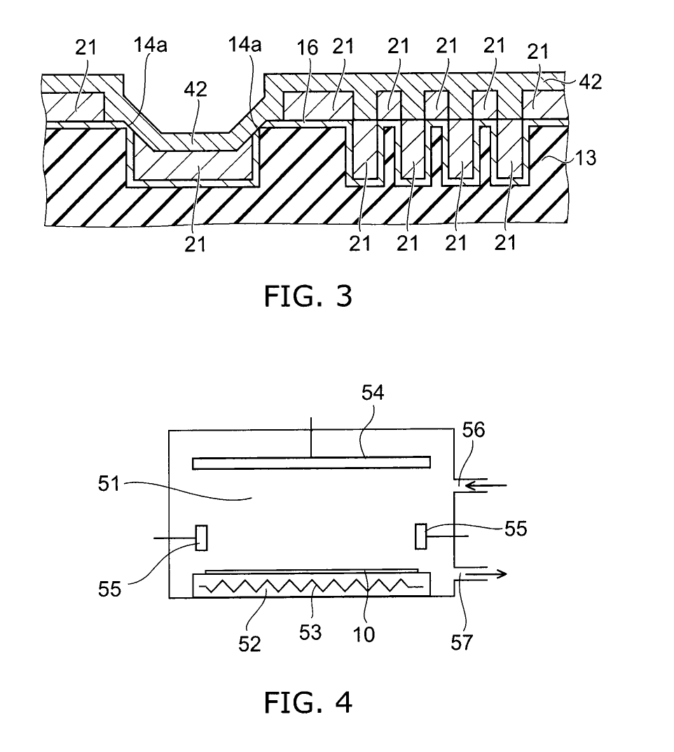

FIG. 4 is a schematic view showing an example of a sputtering system to form the first copper film 21 and the second copper film 22.

A copper target 54 and a wafer 10 are disposed facing each other in a process chamber 51. The wafer 10 is the target on which the first copper film 21 and the second copper film 22 are formed and has a configuration shown in FIG. 1C described above. The side of the substrate 11 of the wafer 10 is supported on a wafer support portion 52. A heater 53 capable of heating the substrate 11 is provided in the wafer support portion 52. Alternatively, the heater 53 may be provided separately from the wafer support portion 52.

A titanium target 55 is provided in the process chamber 51 separately from the copper target 54. The titanium target 55 is provided on the side of a side wall of the process chamber 51 along an outer circumferential direction of the wafer 10. The titanium target 55 is electrically divided into at least two portions. A discharge can be caused between the titanium targets 55 facing each other across the center axis of the wafer 10.

A desired gas is introduced into the process chamber 51 through a gas introducing path 56. The inside of the process chamber 51 is exposed to a decompressed atmosphere cut off from the atmosphere by exhaust through an exhaust path 57.

First, as shown in FIG. 2A, the first copper film 21 is formed by sputtering using the sputtering system. At this time, a discharge is caused between the copper target 54 and the wafer support portion 52 and no discharge is caused between the titanium targets 55. Thus, the first copper film 21 containing almost no impurities other than elements resulting from a discharge gas is formed of copper sputtered from the copper target 54. The titanium composition ratio in the first copper film 21 is lower than 0.01 atomic percent.

When the first copper film 21 is formed by sputtering, the substrate 11 is heated by the heater 53 to a reflow temperature at which copper flows. The reflow temperature is 40° C. or more and the substrate 11 is heated to about 50° C. in the embodiment.

Particularly with copper particles reaching the side of bottom of the second recess 15 that is relatively narrow or has a high aspect ratio flowing and being aggregated, copper film coatability on the side of bottom is improved. The formation of the first copper film 21 by the sputtering process continues until the thickness of the first copper film 21 reaches, for example, 50 nm. As a result, the second recess 15 is completely filled with the first copper film 21 without void.

The first recess 14 having a relatively broad width is not yet completely filled with the first copper film 21. In the first recess 14 having a broad width, coating defects of the first copper 21 tend to arise in a corner portion 14a on the side of opening due to damage during sputtering or aggregation of copper.

Copper particles flying to the corner portion 14a are more likely to flow by being pulled to a portion having a larger volume (copper on the top surface of the insulating layer 13 and copper in the first recess 14) and the amount of copper in the corner portion 14a tends to be insufficient. If the amount of copper is insufficient in the corner portion 14a and the barrier metal 16 or the insulating layer 13 is exposed in the corner portion 14a, no copper is deposited in the corner portion 14a in subsequent electrolytic plating or adhesive properties of the copper film deteriorate, leading to the void.

If a copper film is formed without allowing copper to reflow, copper does not flow in the corner portion 14a, but burying properties of copper film in the second recess 15 having a fine width deteriorate.

Thus, according to the first embodiment, after the first copper film 21 is formed, as shown in FIG. 2B, the second copper film 22 having a higher impurity concentration than the first copper film 21 is formed on the first copper film 21.

The second copper film 22 is an alloy film of copper and titanium. The second copper film 22 contains, for example, 0.01 atomic percent or more of titanium as an impurity to inhibit the aggregation of copper.

When the second copper film 22 is formed, a discharge is caused between the titanium targets 55 in the sputtering system shown in FIG. 4. Accordingly, an alloy film of copper sputtered from the copper target 54 and titanium sputtered from the titanium target 55 is formed on the first copper film 21.

The second copper film 22 is successively formed by sputtering without being released to the atmosphere in the same process chamber 51 as the first copper film 21 formed by sputtering. The temperature of the substrate 11 is maintained at the reflow temperature.

The thickness of the second copper film 22 is set to, for example, 30 nm. The second copper film 22 is formed in the corner portion 14a where coating defects of the first copper film 21 arise in the previous process, with high adhesion strength. When the second copper film 22 is formed, the substrate temperature is maintained at the reflow temperature, but the concentration (composition ratio) of titanium as an impurity in the second copper film 22 is higher than in the first copper film 21.

Thus, the aggregation of copper due to fluidization of copper in the second copper film 22 is inhibited and the second copper film 22 can be formed with lower flowability than the forming the first copper film 21. Thus, the corner portion 14a can reliably be coated.

Because the first copper film 21 and the second copper film 22 can successively be formed by sputtering in the same process chamber 51 without lowering the substrate temperature when the second copper film 22 is formed from the substrate temperature when the first copper film 21 is formed, high productivity can be realized. That is, a process to lower the substrate temperature below the reflow temperature after the first copper film 21 is formed is not needed and there is no need to switch the wafer 10 into another process chamber.

After the second copper film 22 is formed, as shown in FIG. 2C, a third copper film (copper plating film) 23 is formed on a seed layer by the electrolytic plating method using the first copper film 21 and the second copper film 22 as the seed layer. For example, the third copper film 23 is formed to a thickness of 800 nm.

After the third copper film 23 is formed, polishing is performed from the top surface of the third copper film 23 until at least the insulating layer 13 is exposed by, for example, the chemical mechanical polishing (CMP) method. Thus, the top surface of the third copper film 23 and the insulating layer 13 are planarized.

Accordingly, as shown in FIG. 2D, a first interconnection 31 and a second interconnection 32 buried in the insulating layer 13 and having relatively different widths are formed.

The first embodiment, a first comparative example, and a second comparative example are compared and evaluated in terms of the rate of void occurrence. The result is shown in Table 1.

TABLE 1

| | First | Second | | |
|---|---|---|---|---|
| | comparative | comparative | First | Second |
| | example | example | embodiment | embodiment |
| Substrate | 20° C. | 50° C. | 50° C. | 50° C. |
| temperature | | | | |
| Rate of void | 100% | 0% | 0% | 0% |
| occurrence | | | | |
| of | | | | |
| interconnection | | | | |
| width 50 nm | | | | |
| Rate of void | 0% | 74% | 0% | 0% |
| occurrence | | | | |
| of | | | | |
| interconnection | | | | |
| width | | | | |
| 500 nm | | | | |

In the first embodiment, as described above, after the first copper film 21 is formed by sputtering to a thickness of 50 nm in an interconnection groove whose width is 500 nm and an interconnection groove whose width is 50 nm while the substrate temperature is maintained at 50° C. higher than the reflow temperature of copper, the second copper film 22 is formed by sputtering to a thickness of 30 nm. The titanium composition ratio in the first copper film 21 is lower than 0.01 atomic percent and the titanium composition ratio in the second copper film 22 is 0.01 atomic percent or more. Then, the third copper film (copper plating film) 23 is formed to a thickness of 800 nm by the electrolytic plating method using the first copper film 21 and the second copper film 22 as a seed layer.

In the first comparative example, a copper film whose titanium composition ratio is lower than 0.01 atomic percent is formed by sputtering to a thickness of 80 nm in an interconnection groove whose width is 500 nm and an interconnection groove whose width is 50 nm while the substrate temperature is maintained at 20° C. lower than the reflow temperature of copper. Then, a copper plating film is formed to a thickness of 800 nm by the electrolytic plating method using the first copper film as a seed layer.

In the second comparative example, a copper film whose titanium composition ratio is lower than 0.01 atomic percent is formed by sputtering to a thickness of 80 nm in an interconnection groove whose width is 500 nm and an interconnection groove whose width is 50 nm while the substrate temperature is maintained at 50° C. higher than the reflow temperature of copper. Then, a copper plating film is formed to a thickness of 800 nm by the electrolytic plating method using the first copper film as a seed layer.

In the first embodiment, the first comparative example, and the second comparative example, an interconnection groove section is cut out by etching of a focused ion beam (FIB) and then checked for void by the FIB-SEM analysis including an observation using a scanning electron microscope (SEM).

100 interconnections whose width is 500 nm and 100 interconnections whose width is 50 nm are observed. The rate of void occurrence in table 1 corresponds to the number of interconnections in which void is verified, among 100 interconnections.

The rate of void occurrence of the interconnection whose width is 50 nm is 100% in the first comparative example and 0% in the second comparative example. In the first comparative example, the substrate temperature is lower than the reflow temperature of copper and thus, copper is not fluidized and an opening of the interconnection groove whose width is 50 nm is closed before the interconnection groove is completely filled with copper.

The rate of void occurrence of the interconnection whose width is 500 nm is 0% in the first comparative example and 74% in the second comparative example. In the second comparative example, coating defects of the seed layer are caused by fluidization of copper in a corner portion on the side of opening of the interconnection groove whose width is 500 nm, resulting in void.

According to the first embodiment, to bury copper in the first recess 14 and the second recess 15 with relatively different widths simultaneously, the first copper film 21 is formed by the sputtering process at reflow temperature and then the second copper film 22 whose fluidization is inhibited by impurity addition, instead of lowering the substrate temperature, is formed. Accordingly, burying properties of copper in the first recess 14 and the second recess 15 are improved without reducing productivity so that high yields can be gained.

The aggregation of copper occurs when the titanium concentration (composition ratio) in the second copper film 22 is set lower than 0.01 atomic percent, no aggregation of copper occurs when the titanium concentration is set to 0.01 atomic percent or more, which is experimentally verified. Therefore, the titanium concentration (composition ratio) in the second copper film 22 is desirably 0.01 atomic percent or more.

According to the first embodiment, by making the first copper film 21 having a relatively lower titanium concentration and lower resistance thicker than the second copper film 22, a resistance increase of the entire buried copper interconnection can be inhibited. The second copper film 22 only needs to have the thickness with which the corner portion 14a of the first recess 14 having a relatively broad width can reliably be coated.

### Second Embodiment

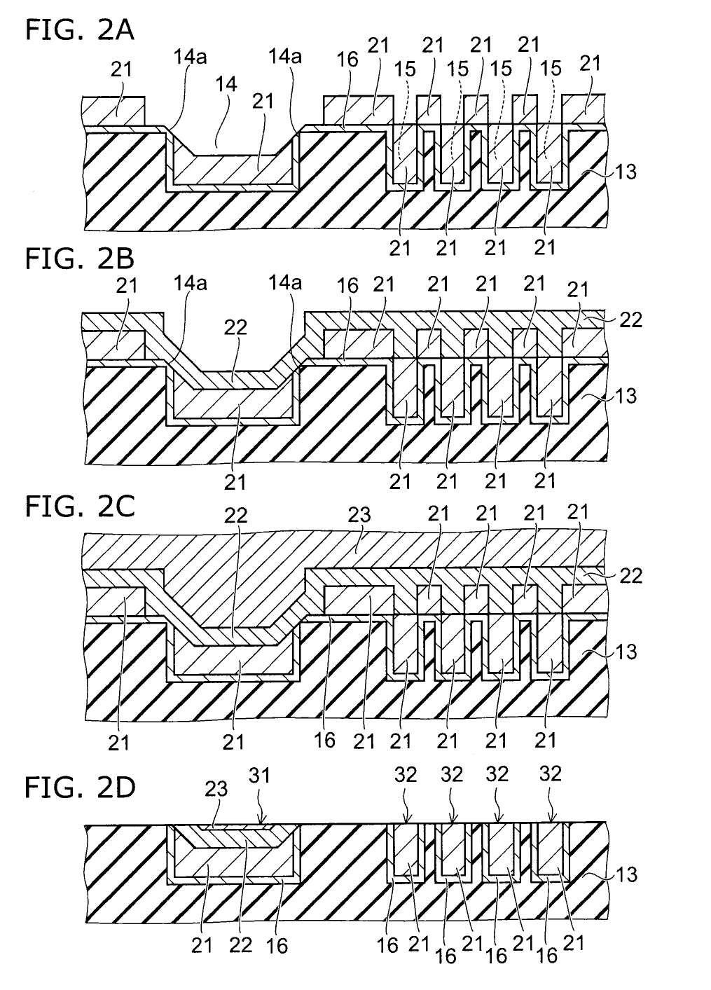

FIG. 3 is a schematic sectional view showing the method for forming a copper interconnection in the method for manufacturing a semiconductor device according to the second embodiment. FIG. 3 corresponds to the process shown in FIG. 2B in the first embodiment.

The second embodiment is the same as the first embodiment except for the formation process of a second copper film. That is, in the second embodiment, after the first copper film 21 is formed, a second copper film 42 containing carbon as an impurity is formed by the sputtering process in a gas atmosphere containing carbon.

For example, a methane gas is introduced into a process chamber at a flow rate of 10 sccm to form a film by sputtering using a copper target. Accordingly, the second copper film 42 contains copper.

As a gas containing carbon, at least one of methane, ethane, ethylene, acetylene, propane, methyl acetylene, methyl amine, and dimethyl amine can be used.

Also in the second embodiment, the substrate temperature is maintained at reflow temperature when the second copper film 42 is formed. The concentration (composition ratio) of carbon as an impurity in the second copper film 42 is higher than in the first copper film 21. Thus, the aggregation of copper due to fluidization of copper is inhibited in the second copper film 42 so that the corner portion 14a of the wider first recess 14 can reliably be coated with the second copper film 42.

Also in the second embodiment, the first copper film 21 and the second copper film 42 can successively be formed by sputtering in the same process chamber without lowering the substrate temperature when the second copper film 42 is formed from the substrate temperature when the first copper film 21 is formed and therefore, high productivity can be realized.

After the second copper film 42 is formed, like in the first embodiment, a third copper film (copper plating film) is formed on a seed layer to a thickness of, for example, 800 nm by the electrolytic plating method using the first copper film 21 and the second copper film 42 as the seed layer.

Then, after the third copper film is formed, polishing is performed from the top surface of the third copper film until at least the insulating layer 13 is exposed by, for example, the CMP method. Thus, the top surface of the third copper film and the insulating layer 13 are planarized. Accordingly, also in the second embodiment, a first copper interconnection and a second copper interconnection buried in the insulating layer 13 and having relatively different widths are formed.

Also the second embodiment is evaluated, like in the first embodiment, in terms of the rate of void occurrence together with the first comparative example and the second comparative example. The result is shown in Table 1 described above.

In the second embodiment, as described above, after the first copper film 21 is formed by sputtering to a thickness of 50 nm in an interconnection groove whose width is 500 nm and an interconnection groove whose width is 50 nm while the substrate temperature is maintained at 50° C. higher than the reflow temperature of copper, the second copper film 42 is formed by sputtering to a thickness of 30 nm. The carbon composition ratio in the first copper film 21 is lower than 0.01 atomic percent and the carbon composition ratio in the second copper film 42 is 0.01 atomic percent or more. Then, the third copper film (copper plating film) is formed to a thickness of 800 nm by the electrolytic plating method using the first copper film 21 and the second copper film 42 as a seed layer.

In the second embodiment, the rate of void occurrence of the interconnection whose width is 50 nm and the rate of void occurrence of the interconnection whose width is 500 nm are both 0%.

Also in the second embodiment, to bury copper in the first recess 14 and the second recess 15 with relatively different widths simultaneously, the first copper film 21 is formed by the sputtering process at reflow temperature and then the second copper film 42 whose fluidization is inhibited by impurity addition, instead of lowering the substrate temperature, is formed. Accordingly, burying properties of copper in the first recess 14 and the second recess 15 are improved without reducing productivity so that high yields can be gained.

The aggregation of copper occurs when the carbon concentration (composition ratio) in the second copper film 42 is set lower than 0.01 atomic percent, no aggregation of copper occurs when the carbon concentration is set to 0.01 atomic percent or more, which is experimentally verified. Therefore, the carbon concentration (composition ratio) in the second copper film 42 is desirably 0.01 atomic percent or more.

By making the first copper film 21 having a relatively lower carbon concentration and lower resistance thicker than the second copper film 42, a resistance increase of the entire buried copper interconnection can be inhibited.

In each of the embodiments described above, a buried interconnection of copper can be formed at low cost by forming a seed layer by the sputtering process and forming a copper plating film by the electrolytic plating method using the seed layer. In the formation of the second copper film 22 in the first embodiment, the film may be formed by sputtering using an alloy target of copper and titanium. In addition to titanium, aluminum may be used as an impurity and a seed layer can be formed with good coating properties by forming the second copper film 22 containing at least one of titanium and aluminum.

Alternatively, a seed layer may be formed by the chemical vapor deposition (CVD) method. For example, a copper film can be formed by the CVD method using an organic metal complex of copper or copper halide as a material.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device, comprising:
forming a first copper film in a first recess and a second recess having a width narrower than the first recess formed in an insulating layer above a substrate while the substrate is heated to a reflow temperature at which copper flows; and
forming a second copper film having an impurity concentration higher than the first copper film above the first copper film with lower flowability than the forming the first copper film.

2. The method according to claim 1, wherein an alloy film containing copper and titanium is formed by a sputtering process as the second copper film.

3. The method according to claim 2, wherein
a titanium composition ratio in the first copper film is lower than 0.01 atomic percent, and
a titanium composition ratio in the second copper film is 0.01 atomic percent or more.

4. The method according to claim 2, wherein the first copper film has a lower titanium composition ratio than the second copper film and is thicker than the second copper film.

5. The method according to claim 1, wherein an alloy film containing copper and aluminum is formed by a sputtering process as the second copper film.

6. The method according to claim 1, wherein the second copper film containing carbon as an impurity is formed by a sputtering process in a gas atmosphere containing the carbon.

7. The method according to claim 6, wherein at least one of methane, ethane, ethylene, acetylene, propane, methyl acetylene, methyl amine, and dimethyl amine is used as a gas containing the carbon.

8. The method according to claim 6, wherein
a carbon composition ratio in the first copper film is lower than 0.01 atomic percent, and
a carbon composition ratio in the second copper film is 0.01 atomic percent or more.

9. The method according to claim 6, wherein the first copper film has a lower carbon composition ratio than the second copper film and is thicker than the second copper film.

10. The method according to claim 1, wherein the first copper film and the second copper film are successively formed in a same process chamber by a sputtering process.

11. The method according to claim 1, further comprising forming a third copper film above a seed layer by an electrolytic plating method using the first copper film and the second copper film as the seed layer.

12. The method according to claim 11, further comprising polishing a top surface of the third copper film to planarize the top surface of the third copper film by a chemical mechanical polishing (CMP) method after the third copper film being formed.

13. The method according to claim 1, further comprising forming a barrier metal conformally along an inner wall of the first recess, an inner wall of the second recess, and an top surface of the insulating layer before the first copper film being formed.

14. The method according to claim 1, wherein a temperature of the substrate is maintained at the reflow temperature when the second copper film is formed.

15. The method according to claim 1, wherein the reflow temperature is 40° C. or more.

16. The method according to claim 1, wherein the second recess is filled with the first copper film.

17. A method for manufacturing a semiconductor device, comprising:
forming a first copper film in a first recess and a second recess having a width narrower than the first recess formed in an insulating layer above a substrate while the substrate is heated to a reflow temperature at which copper flows; and
forming a second copper film having an impurity concentration higher than the first copper film above the first copper film, the first copper film and the second copper film being successively formed in a same process chamber by a sputtering process.

18. The method according to claim 17, further comprising forming a third copper film above a seed layer by an electrolytic plating method using the first copper film and the second copper film as the seed layer.

19. The method according to claim 17, wherein a temperature of the substrate is maintained at the reflow temperature when the second copper film is formed.

20. The method according to claim 17, wherein the second recess is filled with the first copper film.
